(19) United States
(12) Patent Application Publication
(10) Pub. No.: US 2005/0162717 A1
(43) Pub. Date: Jul. 28, 2005

(54) Information recording apparatus

(75) Inventors: Michihiro Fujiyama, Kyotanabe City (JP); Seiji Hashimoto, Daito City (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Moriguchi-City (JP)

(21) Appl. No.: 11/038,414

(22) Filed: Jan. 21, 2005

(30) Foreign Application Priority Data
Jan. 22, 2004 (JP) 2004-014287

(51) Int. Cl. G03F 3/08

(52) U.S. Cl. 358/518

(57) ABSTRACT

An information recording. apparatus comprises pre-recording processing means for circularly recording input images in a nonvolatile memory within a range of areas where a predetermined number of images previously determined can be recorded at the time of the pre-recording processing mode, post-recording processing means for recording input images in order in areas succeeding the area, used for the pre-recording processing in the pre-recording processing mode immediately before the post-recording processing mode, in the nonvolatile memory at the time of the post-recording processing mode, and power restoring processing means for starting, when the power is restored after it is shut off while the pre-recording processing is being performed, post-recording processing in the area succeeding the area used in the pre-recording processing at the time when the power is shut off.

### BACKGROUND OF THE INVENTION

1. Field of the Invention

The present invention relates to an information recording apparatus used for monitoring or the like.

2. Description of the Background Art

In an information recording apparatus for monitoring, video picked up by a monitoring camera is always circularly recorded (pre-recorded) in a volatile memory, and the video pre-recorded in the volatile memory is recorded in a nonvolatile memory, and the video picked up by the monitoring camera is recorded (post-recorded) in the nonvolatile memory for a predetermined time period when a detector for detecting suspicious individuals in a predetermined area, for example, detects the suspicious individual.

When the suspicious individual shuts off the supply power to the information recording apparatus for monitoring and runs away after taking any action in situations where the pre-recording is being performed, information relating to the pre-recording in the volatile memory is erased, so that the video pre-recorded before the power is shut off cannot be left.

### SUMMARY OF THE INVENTION

An object of the present invention is to provide an information recording apparatus capable of leaving video pre-recorded immediately before the power is shut off.

In an information recording apparatus in which a recording processing mode includes a pre-recording processing mode and a post-recording processing mode, the pre-recording processing mode being always set as the recording processing mode, and the recording processing mode being set to the post-recording processing mode during a required time period on the basis of a post-recording instruction input, the present invention is characterized by comprising pre-recording processing means for circularly recording input images in a nonvolatile memory within a range of areas where a predetermined number of images previously determined can be recorded at the time of the pre-recording processing mode; post-recording processing means for recording input images in order in areas succeeding the area, used for the pre-recording processing in the pre-recording processing mode immediately before the post-recording processing mode, in the nonvolatile memory at the time of the post-recording processing mode; and power restoring processing means for starting, when the power is restored after it is shut off while the pre-recording processing is being performed, post-recording processing in the area succeeding the area used in the pre-recording processing at the time when the power is shut off.

For each of the images, for example, in the nonvolatile memory, a recording number representing the time-series order of the image, first control data for determining whether the image is an image inputted at the time of the pre-recording processing mode or an image inputted at the time of the post-recording processing mode, and second control data for indicating, when the image is recorded in the second or subsequent cycle in the area used for the pre-recording processing at the time of the pre-recording processing mode, the area succeeding the area used for the pre-recording processing are recorded as added data.

In this case, an example of the power restoring processing means is one comprising first means for reading out image information and added information from the head of the nonvolatile memory, second means for determining whether or not there exists image information to be read out, third means for starting the post-recording processing, when there exists no image information to be read out, at the position where there has existed no image information to be read out, fourth means for determining, when there exists image information to be read out, whether the image read out this time is recorded before the image read out last time is recorded on the basis of a recording number corresponding to the image read out last time and a recording number. corresponding to the image read out this time, fifth means for reading out, when the image read out this time is not recorded before the image read out last time is recorded, the subsequent image, to perform processing in the second means and the subsequent means, sixth means for determining, when the image read out this time is recorded before the image read out last time is recorded, whether the image read out last time is the image inputted at the time of the pre-recording processing mode on the basis of the first control data corresponding to the image read out last time,. seventh means for starting, when the image read out last time is not the image inputted at the time of the pre-recording processing mode, the post-recording processing at the position where the image is read out this time, and eighth means for reading out, when the image read out last time is the image inputted at the time of the pre-recording processing mode, the image from the area succeeding the area, used for the pre-recording processing, including the image read out last time on the basis of the second control data corresponding to the image read out last time, to perform processing in the second means and the subsequent means.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the configuration of an information recording apparatus for monitoring;

FIG. 2 is a schematic view for explaining conventional pre-recording processing;

FIG. 3 is a schematic view for explaining pre-recording processing according to an embodiment;

FIG. 4 is a flow chart showing the procedure for information recording processing; and

FIG. 5 is a flow chart showing the procedure for power restoring processing.

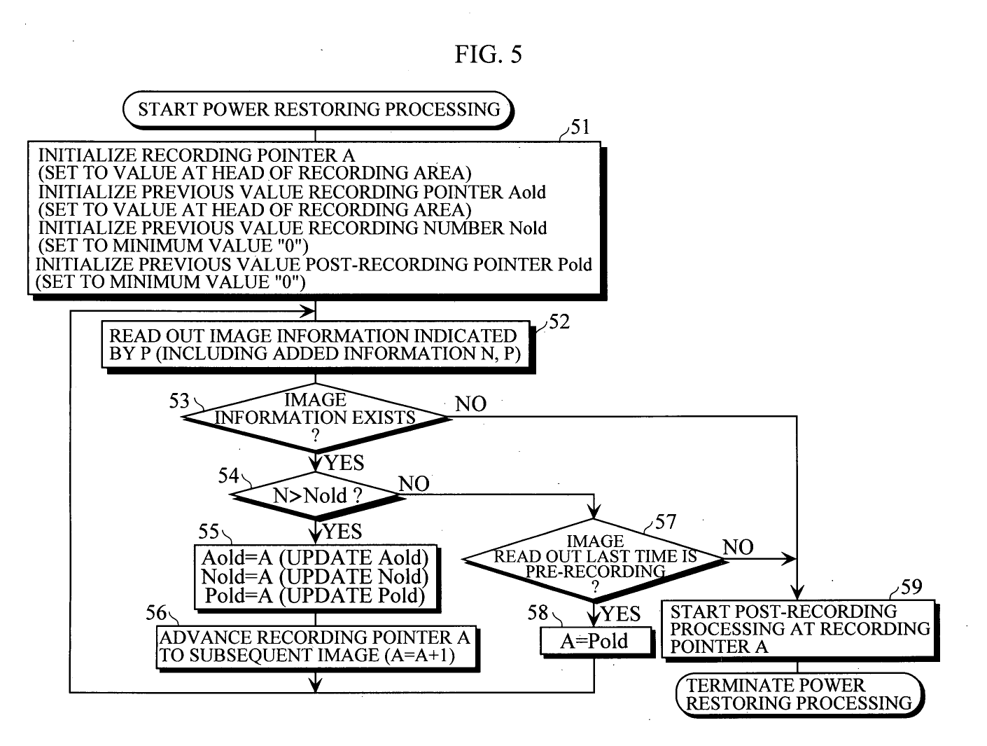

### DESCRIPTION OF THE PREFERRED EMBODIMENTS

Referring now to the drawings, an embodiment of the present invention will be described.

[1] Description of Configuration of Information Recording Apparatus for Monitoring.

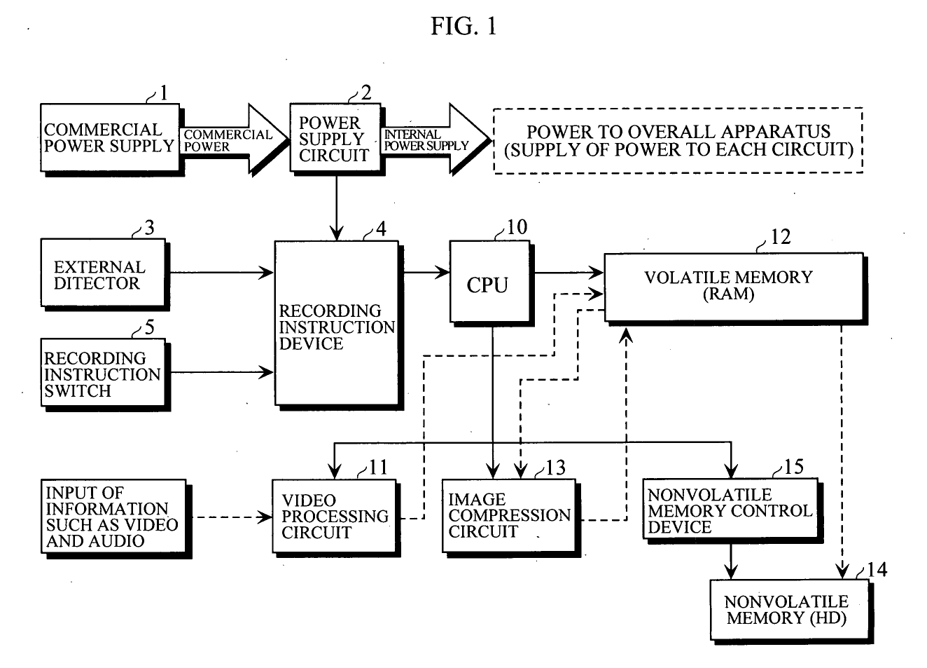

FIG. 1 illustrates the configuration of an information recording apparatus for monitoring. Although an audio signal is actually inputted in addition to a video signal, only the video signal shall be inputted to the information recording apparatus for convenience of illustration.

The commercial power supplied from a commercial power supply 1 is also fed to a power supply circuit 2. The power supply circuit 2 generates the power to each of circuits, and supplies the generated power to the circuit.

An external detector 3 is a detector for detecting that a suspicious individual, for example, breaks into a predetermined area, and outputs an alarm signal when it detects the suspicious individual. The alarm signal is fed to a recording instruction device 4. A recording instruction signal from a recording instruction switch 5 is also inputted to the recording instruction device 4.

The recording instruction device 4 supplies a pre-recording start instruction to a CPU 10 on the basis of the recording instruction signal from the recording instruction device 4 in a state where the power is supplied to the power supply circuit 2. When the alarm signal is inputted in a state where pre-recording is performed, the recording instruction device 4 supplies a post-recording start instruction to the CPU 10. When the power supply is started (the power is restored), the recording instruction device 4 supplies to the CPU 10 an instruction to start power restoring processing.

The CPU 10 performs the power restoring processing in addition to information recording processing. The information recording processing is started on the basis of the pre-recording start instruction based on the recording instruction signal from the recording instruction switch 5 in a state where the power is supplied, and is stopped by a recording stop command from a recording stop key (not shown) Examples of the information recording processing include pre-recording processing and post-recording processing. The pre-recording processing is always performed, and the post-recording processing is performed for a predetermined time period elapsed until the alarm signal is generated. The power restoring processing is performed when the power is restored (when the power is turned on and the failure of the power is restored).

An input image signal is converted into a digital signal by a video processing circuit 11, and is then temporarily stored in a volatile memory 12 such as a RAM. Image data temporarily stored in the volatile memory 12 is fed to an image compression circuit 13 at predetermined timing and compressed, and is then stored in the volatile memory 12. The volatile memory 12 circularly stores the compressed image data corresponding to a predetermined number of frames. The compressed image data stored in the volatile memory 12 is stored in a nonvolatile memory 14 such as a hard disk at predetermined timing. The nonvolatile memory 14 is controlled by a nonvolatile memory control device 15.

Although the compressed image data have been conventionally stored in the nonvolatile memory 14 only at the time of the post-recording processing, the compressed image data are also circularly stored in the nonvolatile memory 14 at the time of the pre-recording processing in the present embodiment.

[2] Description of Difference Between Conventional Pre-Recording and Pre-Recording in the Present Embodiment

[2-1] Description of Conventional Pre-Recording

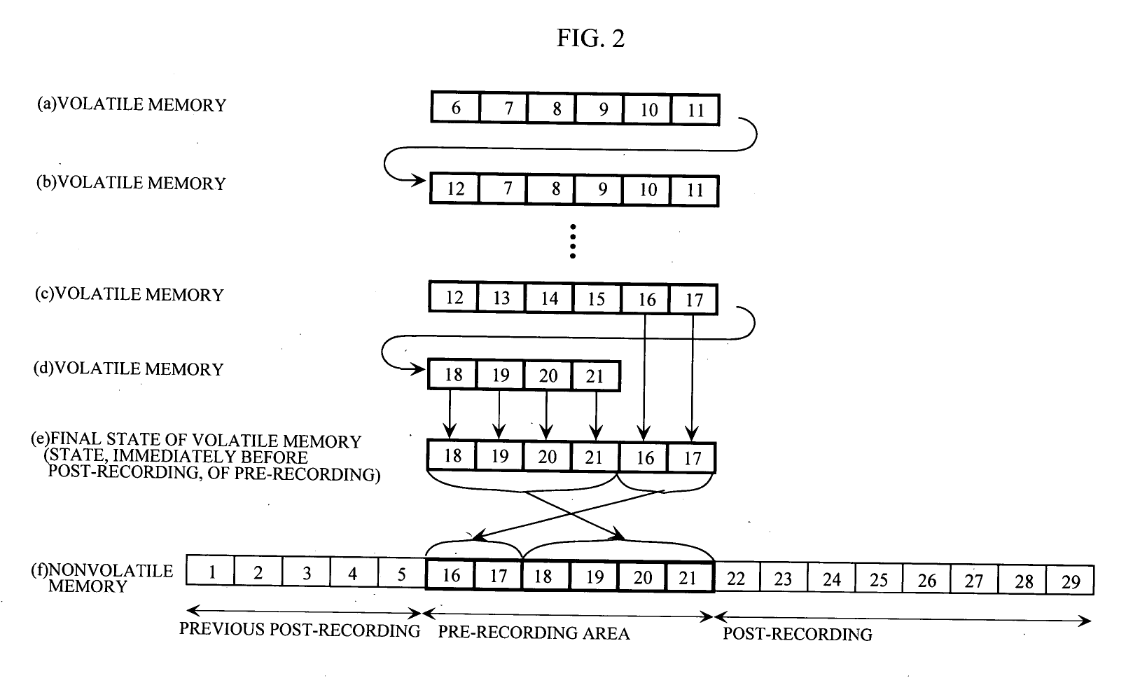

Compressed image data corresponding to six frames shall be circularly stored in a pre-recording area in a volatile memory. As shown in FIGS. 2(a), 2(b), and 2(c), the compressed image data are circularly stored in the volatile memory at the time of pre-recording processing.

When a CPU receives a post-recording instruction at the time point where the compressed image data indicated by a recording number 21 is stored in the volatile memory, as shown in FIG. 2(d), the compressed image data corresponding to six frames recorded in the volatile memory are rearranged on the time series order, as shown in FIG. 2(e), and are then stored in the nonvolatile memory, as illustrated in FIG. 2(f). Post-recording processing is started.

[2-2] Description of Pre-Recording in the Present Embodiment

Compressed image data corresponding to six frames shall be circularly stored in a pre-recording area in the volatile memory 12. Compressed image data corresponding to 12 frames shall be circularly stored in the nonvolatile memory 14 at the time of pre-recording processing.

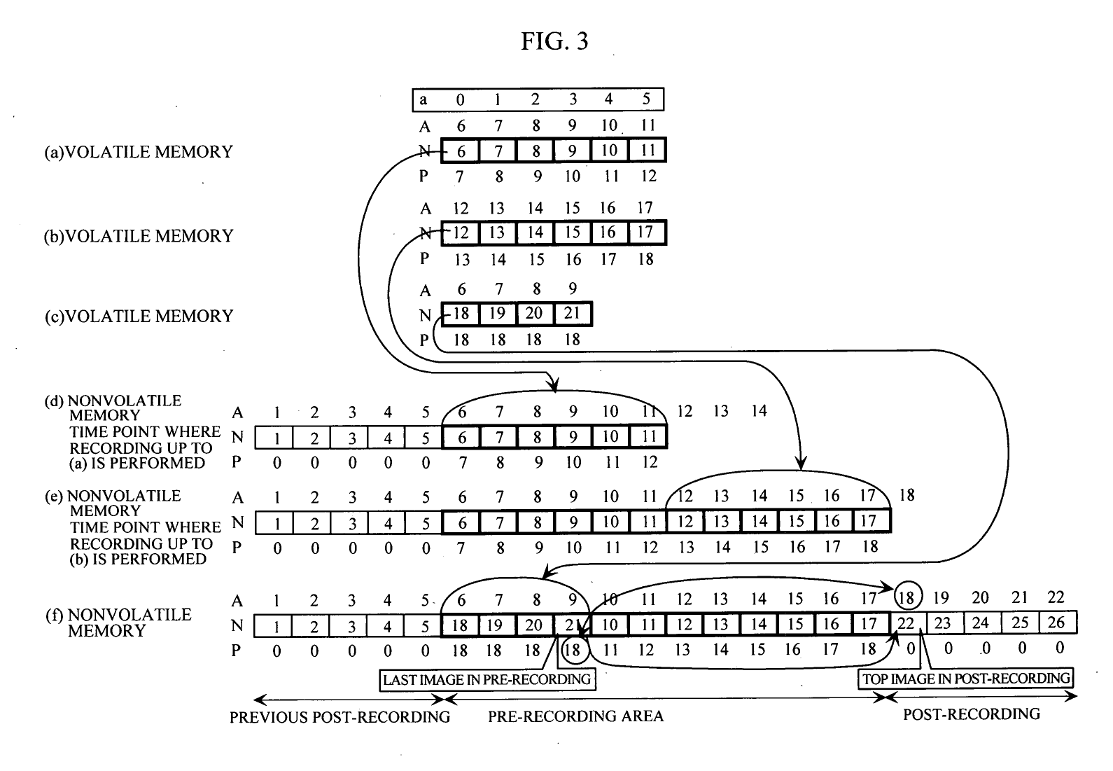

In FIG. 3, each sign has the following meaning;
a : RAM address. A variable representing an address in the volatile memory for storing compressed image data. In this example, there are provided areas respectively storing compressed image data corresponding to six frames. Therefore, a takes a value from 0 to 5 corresponding to the first area to the sixth area 5.
A : Recording address. A variable given as added data to the compressed image data stored in the volatile memory, and representing an address at a destination of writing in storing the compressed image data in the nonvolatile memory.
N : Recording number. A variable given as added data to the compressed image data stored in the volatile memory, and representing an order number assigned for each recording image after recording is started in the information recording apparatus.
P : Post-recording pointer (data which is used as both first control data and second control data). A variable given as added data to the compressed image data stored in the volatile memory. “0” is assigned to an image acquired at the time of post-recording processing, and a value other than “0” is assigned to an image acquired at the time of pre-recording processing.

At the time of the pre-recording processing, the compressed image data are circularly stored, as illustrated in FIGS. 3(a), 3(b), and 3(c), in the volatile memory. In this case, the added data (the recording address A, the recording number N, and the post-recording pointer P) are also stored in addition to the compressed image data in the volatile memory.

When the compressed image data corresponding to six frames are stored, as illustrated in FIG. 3(a), in the volatile memory, the compressed image data corresponding to six frames are stored, as illustrated in FIG. 3(d), in the nonvolatile memory. When the compressed image data corresponding to the subsequent six frames are stored, as illustrated in FIG. 3(b), in the volatile memory, the compressed image data corresponding to six frames are stored, as illustrated in FIG. 3(e), in the nonvolatile memory.

The value of the post-recording pointer P assigned to each of the compressed image data from the time point where the pre-recording is started to the 12-th frame is set to the value of the recording address A to be assigned to the subsequent recording image. The value of the post-recording pointer P assigned to the compressed image data from the time point where the pre-recording is started to the 13-th or subsequent frame is set to the value of the post-recording pointer P assigned to the compressed image data corresponding to the 12-th frame (see FIG. 3(c)). The recording address A assigned to the compressed image data from the time point where the pre-recording is started to the 13-th frame is returned to an address at the head of an area used for pre-recording this time (hereinafter referred to as present pre-recording area) within the nonvolatile memory.

As shown in FIG. 3(c), the compressed image data are sequentially stored in the volatile memory. It is assumed that a post-recording start command is inputted at the time point where the recording number N=21 is stored. When the post-recording start command is inputted, the compressed image data which is recorded in the volatile memory but is not recorded in the nonvolatile memory is recorded in an area, indicated by the recording address A which is data added to the compressed image data, in the nonvolatile memory. As shown in FIG. 3(f), post-recording is started at a recording address corresponding to the value of the post-recording pointer P (“18” in this example) assigned to the last compressed image data in the pre-recording.

[3] Description of Procedure for Pre-Recording Processing and Post-Recording Processing in the Present Embodiment

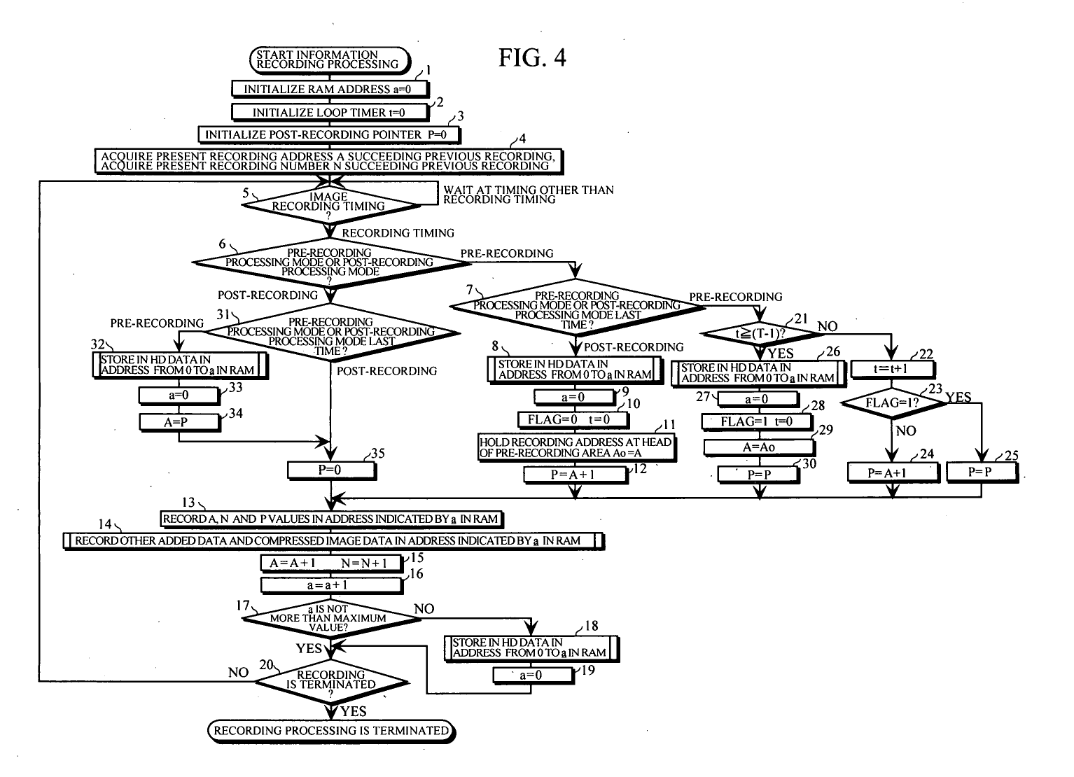

FIG. 4 shows the procedure for information recording processing.

In the following description, the volatile memory 12 shown in FIG. 1 shall be referred to as a RAM, and the nonvolatile memory 14 shall be referred to as an HD. The RAM 12 is provided with an area for temporarily storing an input image, areas (addresses 0 to 5) for storing compressed image data corresponding to six frames, areas for storing various types of variables, and so on. The maximum number of compressed images which can be recorded in the HD 14 at the time of pre-recording can be set, and is previously set as a pre-loop time set value T. In this example, “12” shall be set as the pre-loop time set value T.

When a recording instruction signal from the recording instruction switch 5 is inputted, a variable (a RAM address) a representing an area within the RAM 12 for storing a compressed image is initialized (a=0) (step 1). A variable t used as a loop timer is initialized (t=0) (step 2). Further, a variable P representing a post-recording pointer is initialized (P=0) (step 3).

The present recording address A (a recording address A corresponding to an image acquired this time) which is set in information recording processing performed last time is acquired, and the present recording number N (a recording number N corresponding to an image acquired this time) which is set in the information recording processing performed last time is acquired (step 4).

The timing of recording an image is then waited for (step 5). At the image recording timing, it is determined whether a recording processing mode corresponding to the image acquired this time is a pre-recording processing mode or a post-recording processing mode (step 6).

Description is now made of a case where the recording processing mode corresponding to the image acquired this time is the pre-recording processing mode. In a case where the recording processing mode corresponding to the image acquired this time is the pre-recording processing mode, it is determined whether a recording processing mode corresponding to an image acquired last time is a pre-recording processing mode or a post-recording processing mode (step 7).

In a case where the recording processing mode corresponding to the image acquired last time is the post-recording processing mode (a case where the image acquired this time is N=6 in the example shown in FIG. 3), compressed image data held in an area from the address 0 to the address a in the RAM 12 (compressed image data acquired in the RAM 12 at the time of the post-recording mode) is stored in an area in the HD 14 corresponding to the recording address A added thereto, together with data added to the compressed image data (step 8). In a case where a=0, however, the compressed image data within the RAM 12 has already been stored in the HD 14, so that the processing in the step 8 is not performed. After the processing in the step 8, a is initialized (a=0) (step 9).

In the HD 14, a flag storing the fact that the pre-recording performed this time is in the first cycle (a pre-recording loop flag FLAG) is reset (FLAG=0), and the loop timer t is initialized (step 10) The value of the present recording address A is held as a recording address Ao at. the head of the present pre-recording area within the HD 14. The post-recording pointer P is updated to “A +1” (step 12). “A+1” means a recording address corresponding to an image acquired next time.

The added data A, N, and P are recorded in the area indicated by a within the RAM 12 (step 13). The other added data and compressed image data corresponding to the image data acquired this time are recorded in the area indicated by a within the RAM 12 (step 14).

In order to perform recording processing for the image acquired next time, the recording address A is updated to “A+1”, and the recording number N is updated to “N+1” (step 15). The RAM address a is updated to “a+1” (step 16).

It is determined whether or not a is not more than a value corresponding to the final area in the compressed image data storage area within the RAM 12. (the maximum value : “5” in this example) (step 17). In a case where a is not more than 5, the processing proceeds to the step 20 without storing in the HD 14 the compressed image data within the RAM 12. In a case where a exceeds 5, the compressed image data held in an area from the address 0 to the address a in the RAM 12 is stored in an area in the HD 14 corresponding to the recording address A added thereto, together with data added to the compressed image data (step 18). In a case where a=0, however, the compressed image data within the RAM 12 has already been stored in the HD 14, so that the processing in the step 18 is not performed. After a is initialized (a=0) (step 19), the processing proceeds to the step 20.

In the step 20, it is determined whether or not the recording is terminated (a recording stop command is inputted). If the recording is terminated, the recording processing is terminated. Unless the recording is terminated, the processing is returned to the step 5. In a case where the recording processing mode corresponding to the image acquired last time is the pre-recording processing mode in the foregoing step 7, it is determined whether or not the loop timer t is not less than a value (T−1) which is smaller by one than the pre-loop time set value T (step 21). In a case where t<(T−1), t is updated to “t+1” (step 22). Thereafter, it is determined whether or not the loop flag FLAG is set (step 23). When the loop flag FLAG is not set (FLAG=0), it is determined that the pre-recording performed this time is in the first cycle within the HD 14, to update the post-recording pointer P to “A +1” (step 24). Thereafter, the processing proceeds to the step 13. When the loop flag FLAG is set (FLAG=1), it is determined that the pre-recording performed this time is in the second or subsequent cycle within the HD 14, to maintain the value of the post-recording pointer P as it is (step 25). Thereafter, the processing proceeds to the step 13.

In a case where t≧(T−1) in the foregoing step 21 (a case where the image acquired this time is an image satisfying N=18 in the example shown in FIG. 3), it is determined that the timing is the timing of returning the position where the compressed image data is recorded in the HD 14 to the position at the head of the present pre-recording area, to store the compressed image data held in an area from the address 0 to the address a in the RAM 12 in an area in the HD 14 corresponding to the recording address A added thereto, together with data added to the compressed image data (step 26). In a case where a=0, however, the compressed image data within the RAM 12 has already been recorded in the HD 14, so that the processing in the step 26 is not performed. After this, a is initialized (a=0) (step 27).

Furthermore, the loop flag FLAG is set (FLAG=1), and the loop timer t is initialized (t=0) (step 28). The present recording address A is returned to a recording address Ao at the head of the present pre-recording area within the HD 14 (step 29). That is, A=Ao. Further, the post-recording pointer P is held as it is (step 30). Thereafter, the processing proceeds to the step 13.

Description is made of a case where it is determined in the foregoing step 6 that the recording processing mode corresponding to the image acquired this time is the post-recording processing mode. In a case where the recording processing mode corresponding to the image acquired this time is the post-recording processing mode, it is determined whether the recording processing mode corresponding to the image acquired last time is a pre-recording processing mode or a post-recording processing mode (step 31).

In a case where the recording processing mode corresponding to the image acquired last time is the pre-recording processing mode, the compressed image data held in an area from the address 0 to the address a in the RAM 12 is stored in an area in the HD 14 corresponding to the recording address A added thereto, together with data added to the compressed image data (step 32). In a case where a =0, however, the compressed image data within the RAM 12 has already been recorded in the HD 14, so that the processing in the step 32 is not performed. After this, a is initialized (a=0) (step 33). Further, the recording address A is set to the value of the post-recording pointer P, to set the recording address A to the area succeeding the. area which has been used for the pre-recording immediately before the post-recording (in the example shown in FIG. 3, A=18 in FIG. 3(f)) (step 34). After the value of the post-recording pointer P is set to “0” indicating that the recording is post-recording (P=0) (step 35). Thereafter, the processing proceeds to the step 13.

In a case where it is determined in the foregoing step 31 that the recording processing mode corresponding to the image acquired last time is the post-recording processing mode, the value of the post-recording pointer P is set to 0 (P=0) (step 35). Thereafter, the processing proceeds to the step 13.

[4] Description of Procedure for Power Restoring Processing in the Present Embodiment

First, initialization processing is performed (step 51). That is, the recording pointer A is set to a value at the head of the recording area in the HD 14, and a previous value recording pointer Aold is set to the value at the head of the recording area in the HD 14. A previous value recording number Nold is set to the minimum value “0”. A previous value post-recording pointer Pold is set to the minimum value “0”.

Image information indicated by the recording pointer A (including the added data such as the recording number N and the post-recording pointer P) is then read out of the HD 14 (step 52). It is determined whether or not the read image information includes image data (step 53).

When the read image information does not include image data, the post-recording is started at a position indicated by the recording pointer A (step 59). When the post-recording is performed for a predetermined time period, the power restoring processing performed this time is terminated.

In a case where it is determined in the foregoing step 53 that the read image information includes the image data, it is determined whether or not the recording number N read out this time is more than the recording number read out last time (the previous value recording number) Nold (step 54).

When the recording number N read out this time is more than the previous value recording number Nold (N>Nold), the previous value recording pointer Aold, the previous value recording number Nold, and the previous value post-recording pointer Pold are updated (step 55). That is, the previous value recording pointer Aold, the previous value recording number Nold, and the previous value post-recording pointer Pold are respectively set to the present recording pointer A, the recording number N read out this time, and the post-recording pointer P read out this time. After the recording pointer A is advanced to a position corresponding to the subsequent image (step 56), the processing is returned to the step 52.

In a case where it is. determined in the foregoing step 54 that the recording number N read out this time is not more than the previous value recording number Nold (N≦Nold), it is determined that the image read out this time is recorded before the image read out last time is recorded. Thereafter, the processing proceeds to the step 57. In the step 57, it is judge whether or not the image read out last time is recorded as pre-recording on the basis of the value of the post-recording pointer read out last time (the previous value post-recording pointer Pold). Specifically, when the previous value post-recording pointer Pold is a value other than “0”, it is determined that the image read out last time is an image recorded as pre-recording.

When it is determined that the image read out last time is the image recorded as pre-recording, it is determined that the image read out last time is the last image in the pre-recording. Thereafter, the processing proceeds to the step 58. In the step 58, the previous value post-recording pointer Pold points to the position at the head of the post-recording area succeeding the pre-recording area. Therefore, the recording pointer A is set to the previous. value post-recording pointer Pold. Thereafter, the processing is returned to the step 52.

When it is determined in the foregoing step 57 that the image read out last time is not the image recorded as pre-recording, it is determined that the position indicated by the present recording pointer A is the past recording area other than the pre-recording area and is an area where overwriting recording may be performed, to start the post-recording at the position indicated by the recording pointer A (step 59). When the post-recording is performed for a predetermined time period, the power restoring processing performed this time is terminated.

In the above-mentioned power restoring processing, when the power is shut off while the post-recording processing is being performed, and is thereafter restored, the post-recording processing is started successively from the post-recording processing at the time when the power is shut off. On the other hand, when the power is shut of while the pre-recording processing is being performed, and is thereafter is restored, the post-recording processing is started in the area succeeding the area used in the pre-recording processing at the time when the power is shut off.

Although the present invention has been described and illustrated in detail, it is clearly understood that the same is by way of illustration and example only and is not to be taken by way of limitation, the spirit and scope of the present invention being limited only by the terms of the appended claims.

1. In an information recording apparatus in which a recording processing mode includes a pre-recording processing mode and a post-recording processing mode, the pre-recording processing mode being always set as the recording processing mode, and the recording processing mode being set to the post-recording processing mode during a required time period on the basis of a post-recording instruction input,
an information recording apparatus comprising:
pre-recording processing means for circularly recording input images in a nonvolatile memory within a range of areas where a predetermined number of images previously determined can be recorded at the. time of the pre-recording processing mode;
post-recording processing means for recording input images in order in areas succeeding the area, used for the pre-recording processing in the pre-recording processing mode immediately before the post-recording processing mode, in the nonvolatile memory at the time of the post-recording processing mode; and
power restoring processing means for starting, when the power is restored after it is shut off while the pre-recording processing is being performed, post-recording processing in the area succeeding the area used in the pre-recording processing at the time when the power is shut off.

2. The information recording apparatus according to claim 1, wherein
for each of the images in the nonvolatile memory, a recording number representing the time-series order of the image, first control data for determining whether the image is an image inputted at the time of the pre-recording processing mode or an image inputted at the time of the post-recording processing mode, and second control data for indicating, when the image is recorded in the second or subsequent cycle in the area used for the pre-recording processing at the time of the pre-recording processing mode, the area succeeding the area used for the pre-recording processing are recorded as added data, and
the power restoring processing means comprises
first means for reading out image information and added information from the head of the nonvolatile memory,
second means for determining whether or not there exists image information to be read out,
third means for starting the post-recording processing, when there exists no image information to be read out, at the position where there has existed no image information to be read out,
fourth means for determining, when there exists image information to be read out, whether the image read out this time is recorded before the image read out last time is recorded on the basis of a recording number corresponding to the image read out last time and a recording number corresponding to the image read out this time,
fifth means for reading out, when the image read out this time is not recorded before the image read out last time is recorded, the subsequent image, to perform processing in the second means and the subsequent means,
sixth means for determining, when the image read out this time is recorded before the image read out last time is recorded, whether the image read out last time is the image inputted at the time of the pre-recording processing mode on the basis of the first control data corresponding to the image read out last time,
seventh means for starting, when the image read out last time is not the image inputted at the time of the pre-recording processing mode, the post-recording processing at the position where the image is read out this time, and
eighth means for reading out, when the image read out last time is the image inputted at the time of the pre-recording processing mode, the image from the area succeeding the area, used for the pre-recording processing, including the image read out last time on the basis of the second control data corresponding to the image read out last time, to perform processing in the second means and the subsequent means.
